(19) United States
(12) Patent Application Publication
(10) Pub. No.: US 2005/0093057 A1
(43) Pub. Date: May 5, 2005

(54) Common spacer dual gate memory cell and method for forming a nonvolatile memory array

(76) Inventor: Fu-Chia Shone, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/698,514

(22) Filed: Nov. 3, 2003

(51) Int. Cl. H01L 29/788

(52) U.S. Cl. 257/315

(57) ABSTRACT

In a common spacer dual gate memory cell formed on a semiconductor substrate, two gates for two transistors with a spacer therebetween are arranged in series between two bit lines, and two isolated word lines for the respective gates preferably extends in the directions perpendicular to each other, in which one of the two gates includes a silicon nitride for gate dielectric, and the other gate dielectric also includes a silicon nitride or an oxide only. With the novel structure, up to four charge storage locations are achieved between each pair of the bit lines.

### FIELD OF THE INVENTION

The present invention relates generally to a semiconductor memory, and more particularly, to a nonvolatile memory array composed of common spacer dual gate memory cells.

### BACKGROUND OF THE INVENTION

Among semiconductor memories, nonvolatile memories, especially the electrically erasable programmable read only memory (EEPROM), is particularly useful due to its advantage of retaining information even power is turned off, and its application also becomes more popular. Higher density and higher speed are two most efforts in the development of nonvolatile memories. One approach to increase the memory density is the introduction of multi-level programming systems for the memory cells thereof, which conventionally store one bit per each memory cell. However, more complicated process and peripheral circuitry are needed for the manufacture and operations of a memory when multilevel programmability of the memory cells is used. Basically, each memory cell structure can be applied with multilevel programming system only that proper peripheral circuitry is employed accompanying with the memory array, and simplified operation circuit and method are desired. Another approach for high-density nonvolatile memories is to store two bits in a single memory cell, and there are several prior arts have been proposed, for example U.S. Pat. Nos. 5,768,192, 5,963,465 and 6,011,725 issued to Eitan. Similar to other semiconductor memories, the nonvolatile memory is also developed toward scale down to increase the memory capacity, and new and improved memory cell structures and better programming mechanisms are proposed to improve the performance thereof. To increase the density of memory circuit and simplify its manufacture process, oxide-nitride-oxide (ONO) structure has been used to replace the conventional stack memory cell. Further increment of memory density is provided for example by U.S. Pat. No. 5,424,569 issued to Prall and U.S. Pat. No. 6,248,633 issued to Ogura et al.

A two-bit nonvolatile memory cell disclosed in U.S. Pat. No. 6,011,725 is provided herewith in FIG. 1 to illustrate its structure and operations. On a semiconductor substrate 10, two bit lines 12 and 14 are formed with a gate above therebetween. The gate includes a gate dielectric such as a silicon nitride 18 sandwiched between two oxides 16 and 20 and a control gate 22 on the gate dielectric. The silicon nitride 18 is programmable with two bits 24 and 26 on its two sides next to the bit lines 12 and 14, respectively. Even this art increases the memory capacity, its operations become complicated. Specifically, the left bit 24 and right bit 26 are read in opposite directions, as designated in FIG. 1, and their control and corresponding circuit become complicated. Moreover, multi-level programming is difficult to implement in this memory cell.

Another memory cell is proposed by Sasago et al. in “10-MB/s Multilevel Programming of Gb-Scale Flash Memory Enabled by New AG-AND Cell Technology”, IEEE IEDM, p. 952-955 (2002). The cell structure of this art is provided in FIG. 2, in which a semiconductor substrate 28 is implanted with punch through regions 30 and bit lines 32, a gate oxide 34 and its corresponding assist gate 36 are formed above between the punch through region 30 and bit line 32, a tunnel oxide 38 and a floating gate 40 are formed above the other side of the punch through region 30 between another bit line 32, an ONO dielectric 42 is formed on the floating gate 40, and a polysilicon 44 is further formed thereon. This art achieves a high speed multi-level programming, while brings complex circuit of the memory cell and its control circuit.

There is still a need of modified or new cell structure advantageous to nonvolatile memories. Also, the operation method and thus the circuit for conventional nonvolatile memories are still so complicated that improvement is desired. Therefore, the present invention is directed to beneficial memory cell structures for high-density nonvolatile memories.

### SUMMARY OF THE INVENTION

Accordingly, it is an object of the present invention to disclose a novel memory cell by which the nonvolatile memory array thus constructed has increased density and the method to manipulate the memory is simplified.

In a common spacer dual gate memory cell, according to the present invention, two gates isolated by a spacer therebetween are provided for a pair of bit lines, and these two gates have their word lines preferably extending along directions perpendicular to each other.

Particularly, at least one of the gates in the invented memory cell comprises a silicon nitride in the gate dielectric. The other gate dielectric of the cell comprises an oxide only or a silicon nitride also. The gate dielectric including a silicon nitride preferably employs an ONO structure. Up to four bits are achieved when both of the gate dielectrics in the memory cell include ONO structure for charge storages in a binary system, and with the inventive memory cells, a nonvolatile memory array of higher density is obtained.

Methods for forming a nonvolatile memory array composed of the proposed memory cells are also provided.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIG. 1 shows a prior art of two bit nonvolatile memory cell;

FIG. 2 shows a prior art of AG-AND-type memory cell;

FIG. 3 shows a nonvolatile memory array constructed with a plurality of first embodiment memory cells according to the present invention;

FIG. 4 shows the circuit diagram of the memory array shown in FIG. 3;

FIGS. 5-10 show an embodiment process for forming the memory array of FIG. 3;

FIG. 5 shows the structure after an ONO dielectric, a polysilicon and its cap are formed on a substrate;

FIG. 6 shows the structure after the first gates are patterned and bit lines and punch through regions are implanted;

FIG. 7 shows the structure after the portion of the first ONO dielectric at the spacers between the first gates is removed;

FIG. 8 shows the structure after a CVD oxide for spacers is deposited;

FIG. 9 shows the structure after the common spacers are formed by etching the CVD oxide shown in FIG. 8 and a second ONO dielectric is then formed thereon;

FIG. 10 shows the structure after the second control gates are formed;

FIG. 11 shows a nonvolatile memory array constructed with a plurality of second embodiment memory cells according to the present invention;

FIG. 12 shows the circuit diagram of the memory array shown in FIG. 11;

FIGS. 13-18 show an embodiment process for forming the memory array of FIG. 11;

FIG. 13 shows the structure after an oxide, a polysilicon and its cap are formed on a substrate;

FIG. 14 shows the structure after the first gates are patterned and bit lines are implanted;

FIG. 15 shows the structure after the portion of the oxide dielectric at the spacers between the first gates is removed;

FIG. 16 shows the structure after a CVD oxide for spacers is deposited;

FIG. 17 shows the structure after the common spacers are formed by etching the CVD oxide shown in FIG. 16 and an ONO dielectric is then formed thereon; and

FIG. 18 shows the structure after the second control gates are formed.

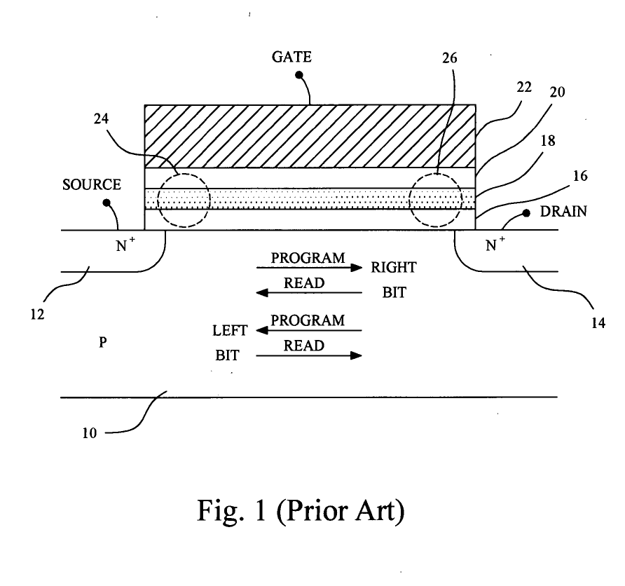

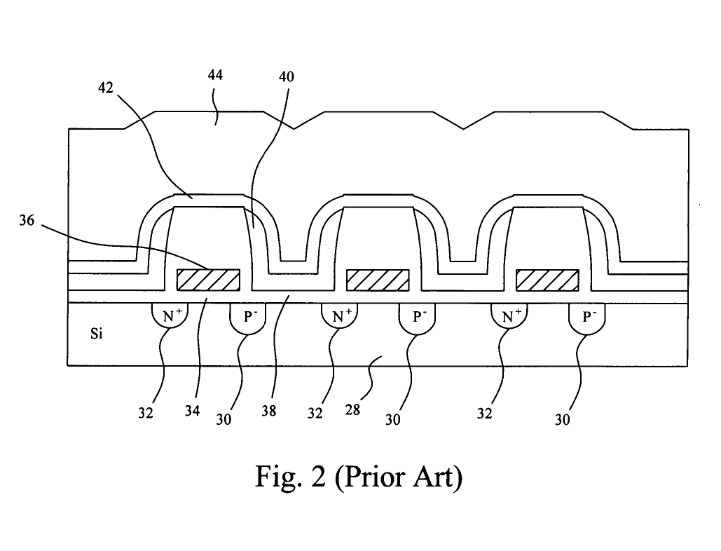

### DETAILED DESCRIPTION OF THE INVENTION

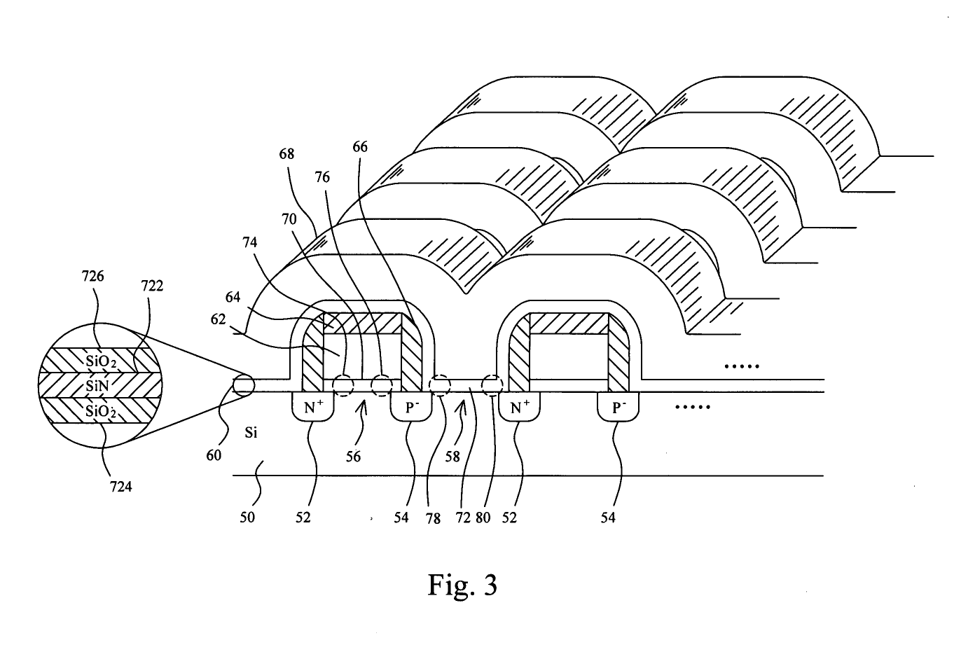

The structure of a preferred embodiment nonvolatile memory array according to the present invention is shown in FIG. 3. On a semiconductor substrate 50, in addition to a plurality of bit lines 52, a plurality of punch through regions 54 are optionally formed each between a pair of the bit lines 52 and as a result, two channels 56 and 58 are formed on the opposite sides of each punch through region 54 between its neighbor bit lines 52. Above the substrate 50, a control gate 62 formed of a conductor for example polysilicon enclosed by a cap 64 and spacers 66 is formed corresponding to the channel 56 with an ONO gate dielectric 70 therebetween. The cap 64 is made of an oxide or silicon nitride or other available insulator. On the other hand, another channel 58 also has a corresponding ONO gate dielectric 72, above which is a second control gate 68 extending along a direction preferably perpendicular to that of the first control gate 62 and crossing over above the first control gate 62 and spacers 66 insulated from the control gate 62 by the cap 64 and spacer 66. Similarly, the second control gate 68 is made of a conductor, such as polysilicon. The spacer 66 further isolates the first ONO dielectric 70 from the other one 72. For illustration, even it is well known, a circle designated with 60 is enlarged to show a silicon nitride 722 sandwiched by two silicon dioxide 724 and 726 in the ONO dielectric 72. Likewise, the other ONO dielectric 70 has such a sandwich structure. As such, a common spacer dual gate memory cell is constructed between each pair of the bit lines 52, and within each memory cell, two transistors are included on the opposite sides of the spacer 66 with the two bit lines 52 next to the memory cell as their source/drain. This memory cell uses hot electron programming and channel tunneling erasing. By applying different operating voltages on the control gates 62 and 68 and bit lines 52, charge can be stored in the ONO dielectrics 70 and 72 next to the spacer 66 and next to the bit lines 52. Since the ONO dielectric 70 or 72 can be programmed by storing charges on either one of the opposite sides thereof, this embodiment structure achieves up to four charge storage locations designated by 74, 76, 78 and 80. In a binary system, for the two bits 76 and 78 next to the spacer 66, source side injection is employed for low current and high speed programming thereto, and during the programming, drain voltage is extended thereto by properly applying bias on the control gates 62 and 68. Alternatively, to program the other two bits 74 and 80 next to the bit lines 52, hot electron injection is employed. To erase each of these four bits 74, 76, 78 and 80, negative high voltage is applied on the corresponding gate 62 or 68 to perform channel tunneling erasing.

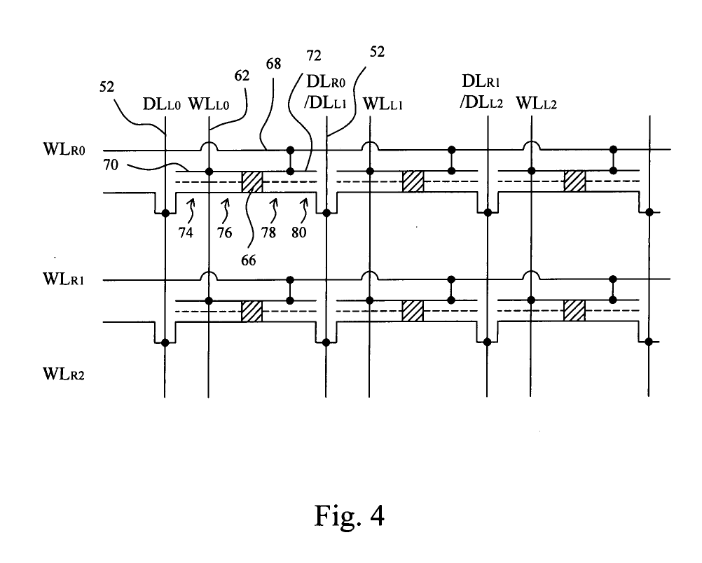

For convenience of explanation, by selecting the spacer 66 as a reference, the memory cell can be referred with a left transistor on the left hand and a right transistor on the right hand. In the same manner, the bits 76 and 78 next to the spacer 66 are referred to left bit and right bit, respectively, and the other two 74 and 80 next to the bit lines 52 are referred to left left bit and right right bit, respectively. The circuit of the memory array shown in FIG. 3 is provided in FIG. 4, and in which some reference numbers used in FIG. 3 are also designated for correspondence between these two drawings. To the spacer 66 between two neighbor bit lines DL_{L0} and DL_{L1}, the left transistor has the ONO dielectric 70 connected with a word line WL_{L0}, i.e., the control gate 62, and the right transistor has the ONO dielectric 72 connected with another word line WL_{R0}, i.e., the control gate 68. For the correspondence of FIG. 3, the word lines WL_{L0} and WL_{R0} are shown in vertical and horizontal directions respectively and thus perpendicular to each other in FIG. 4. The operations of the memory cell or these two transistors are listed in Tables 1-4 for the four bits 74, 76, 78 and 80 under binary system. Briefly, when the left transistor is programmed or read, the right one is completely turned on, and thus the left transistor is operated as a two-bit flash memory cell, of which one bit may be programmed by hot electron mechanism, and the other one may be programmed by source-side injection mechanism. However, the corresponding voltages are a bit different. Referring to FIG. 3, preferably, the left left bit 74 has a threshold voltage higher than that of the left bit 76. For example, they are assumed V_{tLL,PGM}=5 V and V_{tL,PGM}=3.5 V for the left left bit 74 and left bit 76, respectively. Likewise, the right bit 78 and right right bit 80 have the threshold voltages of V_{tR,PGM}=3.5 V and V_{tRR,PGM}=5 V, respectively. Moreover, each of bit 74, 76, 78 and 80 has an erase voltage Vₜₑ of 1.5 V.

Source-side injection is used to program the left bit 76 of the ONO gated memory cell. In this case, the right transistor is completely turned on by a gating voltage VWL_{R0} not smaller than 5 V to extend the drain voltage VDL_{R0} to the right side of the spacer 66, and the left transistor is also completely turned on by a gating voltage VWL_{L0} not smaller than 5 V to extend the source voltage VDL_{L0} of for example 5 V next to the left side of the spacer 66. Thus, a large voltage difference, i.e., VDL_{L0}−VDL_{R0}, is established between the spacer 66, resulting in a high field electron injection into the ONO gate dielectric 70 next to the left side of the spacer 66 due to high drain and gate voltages on the left transistor. To read the left bit 76, the right transistor is also completely turned on by a gating voltage VWL_{R0} not smaller than 5 V, and the left bit 76 is sensed by a gating voltage VWL_{L0} ranged between 3.5 V and 1.5 V, i.e., between the threshold voltages of the left bit 76 being programmed and erased, under a slightly large drain voltage VDL_{L0} of for example not smaller than 1 V applied to assure the left bit 76 of being properly read no matter the left left bit 74 is ever programmed or not. To erase the left bit 38, the right transistor is blocked by a zero gating voltage VWL_{R0} , both bit lines DL_{L0} and DL_{R0} are grounded, and a very large negative voltage for example −10 V is applied on the left gate WL_{L0} for channel tunneling erasing. The voltages for various operations of the left bit 76 are summarized in Table 1.

TABLE 1

| Mode | VWL_{L0} | | VWL_{R0} | | VDL_{L0} | | VDL_{R0} |
|---|---|---|---|---|---|---|---|
| Read | 1.5 V to | | ≧5 | V | ≧1 | V | 0 V |
| | 3.5 V | | | | | | |
| Program | ≧5 | V | ≧5 | V | 5 | V | 0 V |
| Erase | −10 | V | 0 | V | 0 | V | 0 V |

For the right bit 78, since it is symmetrical to the spacer 66 with the left bit 76 in this embodiment, the conditions for its operations are similar to Table 1 with interchanges of the source/drain and gate voltages, as shown in Table 2.

TABLE 2

| Mode | VWL_{L0} | | VWL_{R0} | | VDL_{L0} | VDL_{R0} | |
|---|---|---|---|---|---|---|---|
| Read | ≧5 | V | 1.5 V to | | 0 V | ≧1 | V |
| | | | 3.5 V | | | | |
| Program | ≧5 | V | ≧5 | V | 0 V | 5 | V |
| Erase | 0 | V | −10 | V | 0 V | 0 | V |

The situation for the operations of the left left bit 74 is some different from that of the left bit 76, as shown in Table 3. To program thereto, for example, the gates WL_{L0} and WL_{R0} both are applied with 6 V, and 6 V and 0 V are applied on the bit lines DL_{L0} and DL_{R0}, respectively. Under this condition, the right transistor and left bit 76 are both turned on. When the voltage difference between the gate WL_{L0} and drain DL_{R0} is larger than the threshold, i.e., VDL_{R0}≧V_{g,}WL_{L0}−V_{te,}WL_{L0}, the bit 74 is programmed by hot electron injection. To read the bit 74 thereof, the gate WL_{L0} is biased ranging from 3.5 V to 5 V and the gate WL_{R0} is applied with for example 6 V thereon, while a small voltage drop of about 0.1 V is applied across between the source DL_{R0} and drain DL_{L0}. Likewise, to erase the bit 74, the right transistor is blocked by a zero gating voltage VWL_{R0}, both bit lines DL_{L0} and DL_{R0} are grounded, and a very large negative voltage for example −10 V is applied on the left gate WL_{L0} for channel tunneling erasing.

TABLE 3

| Mode | VWL_{L0} | VWL_{R0} | VDL_{L0} | VDL_{R0} |
|---|---|---|---|---|
| Read | 3.5 V to 5 V | 6 V | 0.1 V | 0 V |
| Program | 6 V | 6 V | 6 V | 0 V |
| Erase | −10 V | 0 V | 0 V | 0 V |

Due to the symmetry, the conditions for the right right bit 80 are obtained by interchanging the source/drain and two gates and are shown in Table 4.

TABLE 4

| Mode | VWL_{L0} | VWL_{R0} | VDL_{L0} | VDL_{R0} |
|---|---|---|---|---|
| Read | 6 V | 3.5 V to 5 V | 0 V | 0.1 V |
| Program | 6 V | 6 V | 0 V | 6 V |
| Erase | 0 V | −10 V | 0 V | 0 V |

To those skilled in the art, it is obvious to set different thresholds for the two transistors of the common spacer dual gate memory cell by the same operation mechanisms illustrated in the above.

To those skilled in the art, furthermore, it is possible to modify the memory cell to have more than two transistors arranged in series between each pair of bit lines by introducing more control gates or to have more than two charge storage locations in an ONO dielectric. However, the number of available bits in a memory cell with the invented structure is selectively determined. For example, there may be one bit programmable in each transistor or only one charge storage location for multi-programmability in a gate dielectric, even the ONO dielectric is utilized for the gate dielectric.

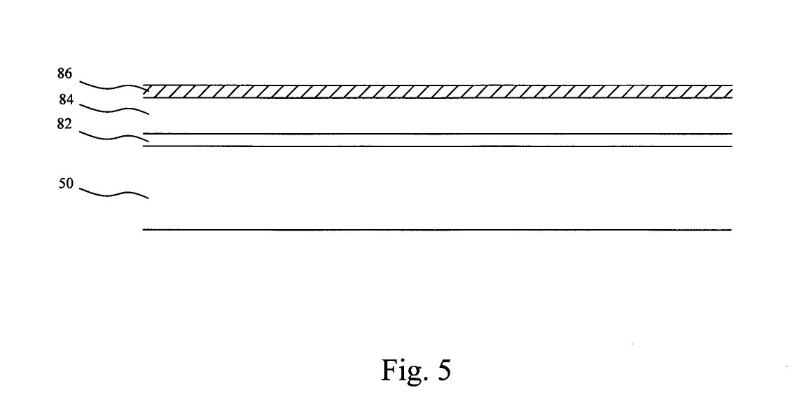

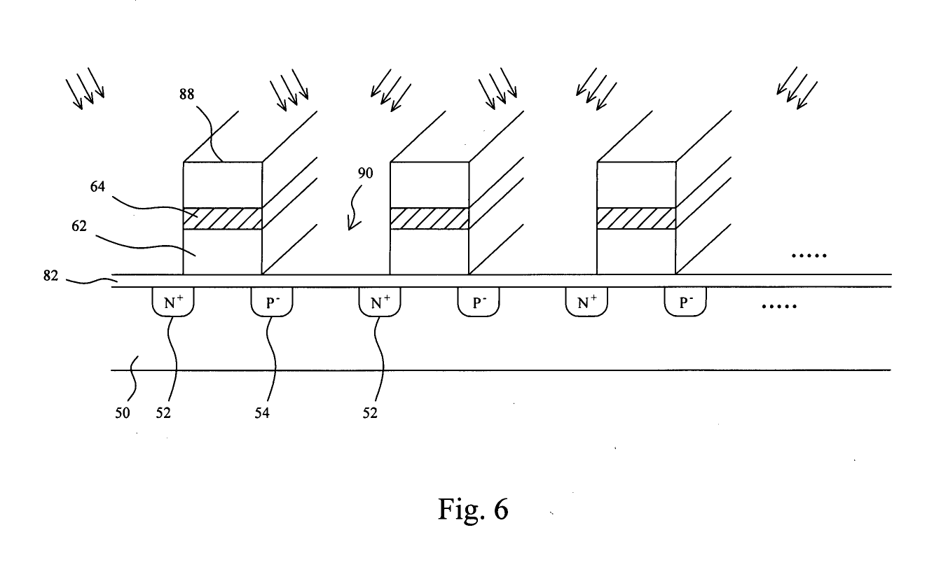

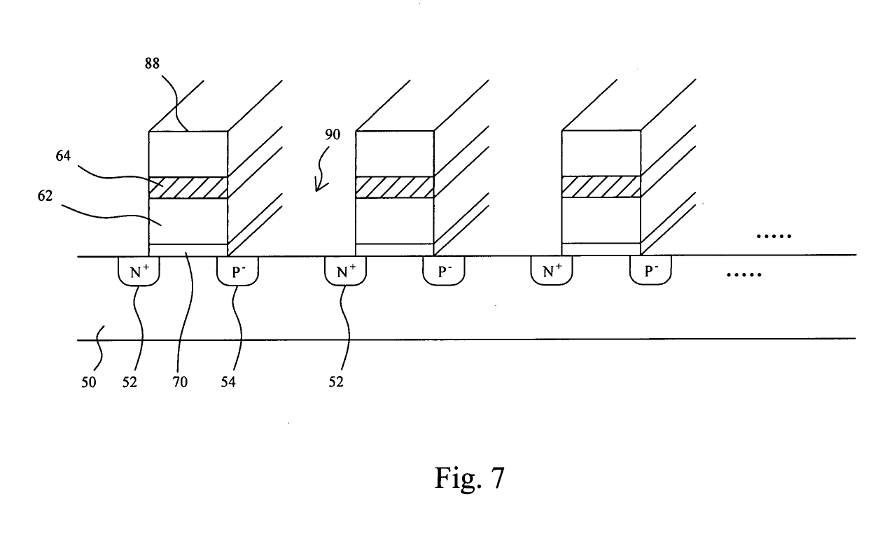

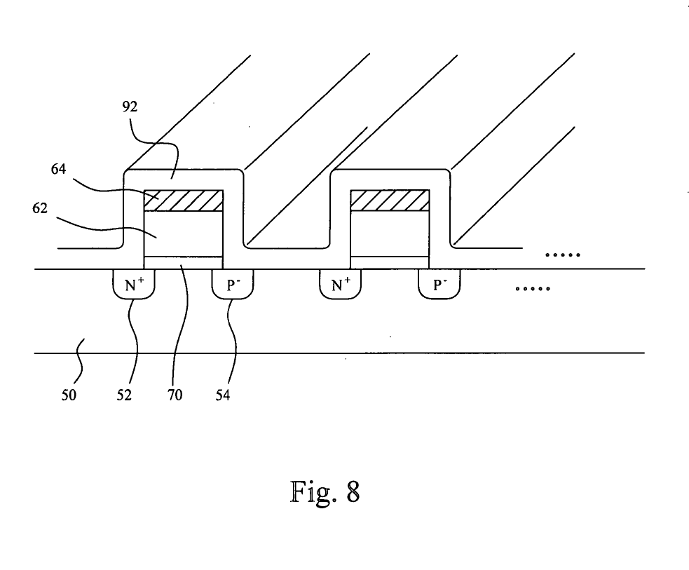

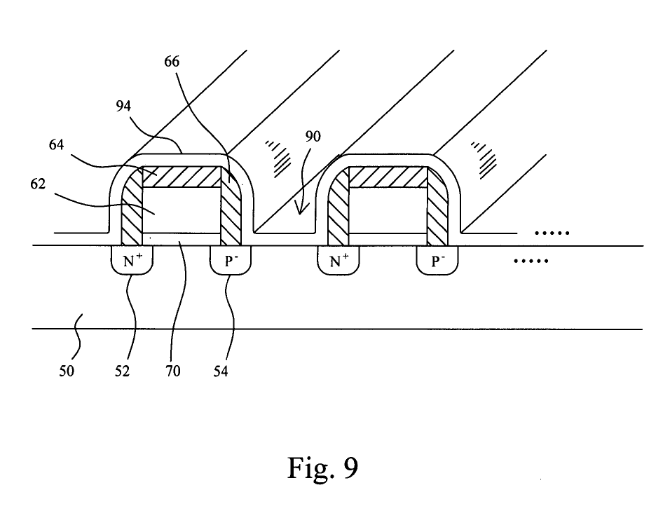

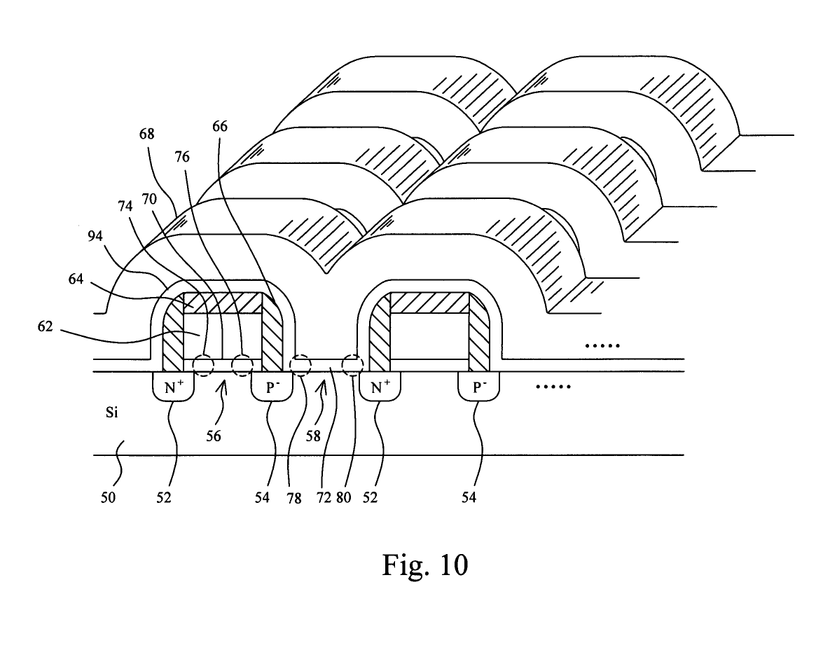

FIGS. 5-10 provides an embodiment process for forming the memory array shown in FIG. 3. In FIG. 5, the substrate 50 is formed with an ONO dielectric 82, a polysilicon 84 and a silicon nitride or silicon dioxide cap 86 thereon. Then the structure is patterned to define the first gates with a photoresist 88, as shown in FIG. 6. After this patterning procedure, the polysilicon 84 and cap 86 are etched to form the poly-gate 62 and its cap 64 and expose the underlying ONO dielectric 82 at the spaces 90 between the poly-gates 62. Two steps of tilt implantations with Arsenic and Boron or extra masking steps are performed through the spaces 90 to form the bit lines 52 and punch through regions 54 on the substrate 50. The ONO dielectric 82 is then etched by self-aligned process to completely remove its portion at the spaces 90, as shown in FIG. 7, and thus leave the first gates dielectric 70 underneath the poly-gates 62. The photoresist 88 is further stripped off. As shown in FIG. 8, a CVD oxide 92 or other insulator is deposited and then etched to form spacers 66 of 100 A to 800 A in width on the sidewalls of the first gates, as shown in FIG. 9, and an ONO dielectrics 94 is further formed thereon. As shown in FIG. 10, then the second poly-gates 68 are formed by depositing a polysilicon, forming Tungsten silicide thereon and patterning the polysilicon and silicide.

Alternatively, the cap 86 on the polysilicon 84 can be formed by oxidization of the surface of the polysilicon 84, and the sidewall spacer 66 can be also obtained by oxidizing the surface of the poly-gate 62.

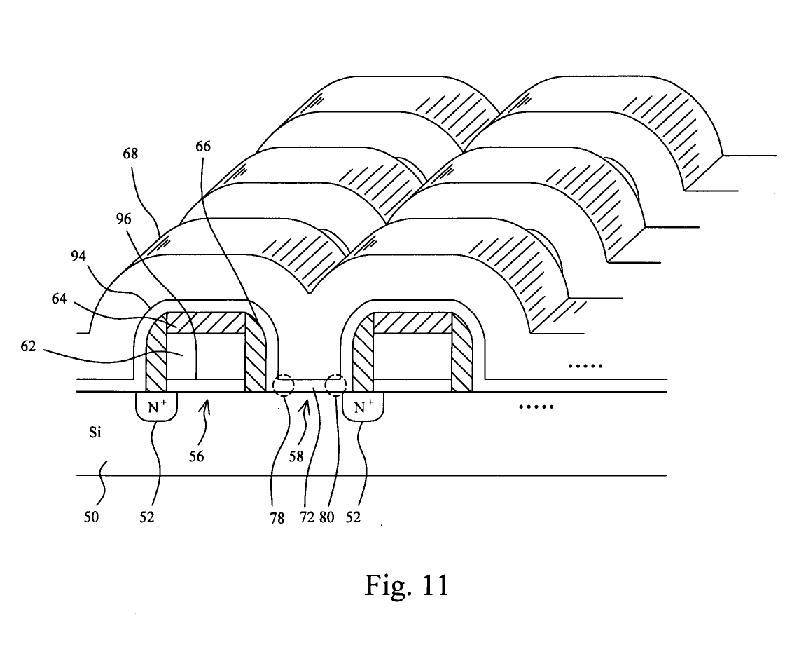

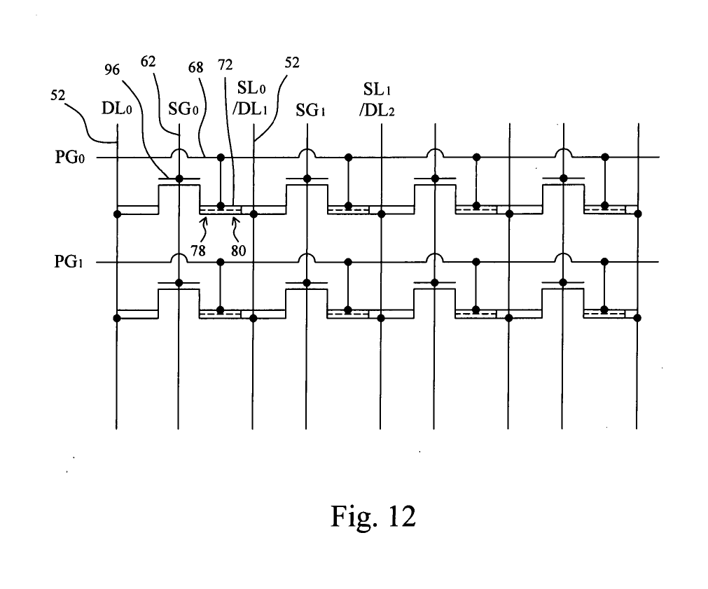

A second embodiment nonvolatile memory array according to the present invention is shown in FIG. 11, which is so designed similar to that of FIG. 3, only that the first gate dielectric 96 is replaced with an oxide only. The poly-gate 62 enclosed with a cap 64 and spacers 66 is spaced from the channel 56 with the gate oxide 96 therebetween, and the ONO dielectric 72 at the space between the poly-gates 62 still serves as the second gate dielectric. In this structure, the left transistor is similar to that of a conventional oxide gated memory cell, and the right one is the same as that in the first embodiment shown in FIG. 3. The left transistor herewith is serving as a gating device, and the right one is still as a memory cell programmable with one or more locations or multi-bits. The circuit of this memory array is shown in FIG. 12, in which the control gate 62 of the left transistor is SG₀ and the second control gate 68 (PG₀) is connected to the ONO dielectric 72. The operations of these two transistors are listed in Tables 5 and 6 under binary system.

In this embodiment, the program thresholds of the bits 78 and 80 are assumed with 3.5 V and 5 V, and their erase voltage is 1.5 V, as of the first embodiment. Source-side injection is used to program the left bit 78 of the ONO gated memory cell. In this case, as shown in Table 5, the left transistor is completely turned on by applying a voltage larger than its threshold for example 0.2 V to 2 V on its gate SG₀ and 0 V on its source DL₀, and the drain DL₁ and the gate PG₀ of the right transistor are applied with 5 V and larger than 6 V, respectively, so as to form a high voltage difference between the spacer 66 and therefore high field electron injection into the ONO dielectric 72 next to the right side of the spacer 66 due to high voltages on the gate PG₀ and drain DL₁ of the memory cell. For the other bit 80, the left transistor is completely turned on by applying a voltage between 0.2 V to 2 V on its gate SG₀ and 0 V on its source DL₀, and the gate PG₀ of the right transistor is applied with a voltage between 3.5 V to 5 V to turn on the left bit 78, so as to extend the source voltage VD_{L0} to the right bit 80. In addition, the drain DL₁ is applied with for example 5 V for the voltage difference between the gate PG₀ and drain DL₁ larger than the threshold, i.e., VDL₁≧VPG₀−Vₜₑ, such that the bit 80 is programmed by hot electron injection into the ONO dielectric 72 next to the bit line 52.

TABLE 5

| Programming | VSG₀ | VPG₀ | VDL₀ | VSL₀/VDL₁ |
|---|---|---|---|---|
| Bit 78 | 0.2 V to 2 V | >6 V | 0 V | 5 V |
| Bit 80 | 0.2 V to 2 V | 3.5 V to 5 V | 0 V | 5 V |

To read the bits 78 and 80, the conditions are shown in Table 6. Either reading the bit 78 or 80, the left transistor is gated with for example 0.2 V to 2 V to be turned on so as to operate the right transistor. For the bit 78, it is sensed by a gating voltage VPG₀ ranged between 1.5 V and 3.5 V, i.e., between the threshold voltages of the left bit 78 being programmed and erased, and DL₁ is serving as the drain and supplied with a slightly large voltage for example 1 V to assure proper reading is performed no matter the bit 80 is ever programmed or not. To read the other bit 80, the right gate PG₀ is applied with a voltage between 3.5 V and 5 V, and a small voltage drop of about 0.1 V is provided across the bit lines DL₁ and DL₀.

TABLE 6

| Reading | VSG₀ | VPG₀ | VDL₀ | VSL₀/VDL₁ |
|---|---|---|---|---|
| Bit 78 | 0.2 V to 2 V | 1.5 V to 3.5 V | 0 V | 1 V |
| Bit 80 | 0.2 V to 2 V | 3.5 V to 5 V | 0 V | 0.1 V |

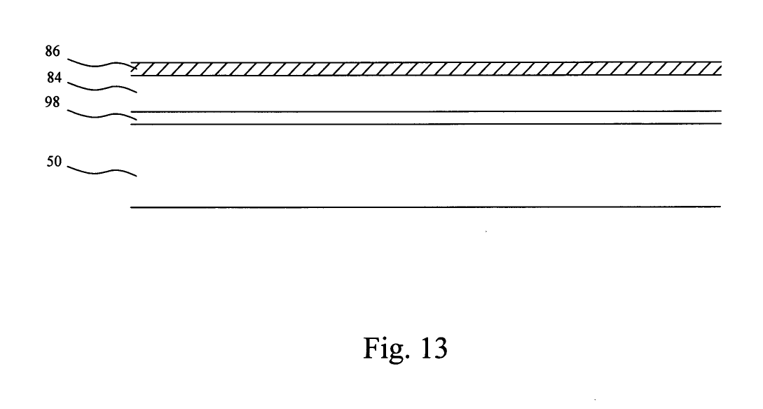

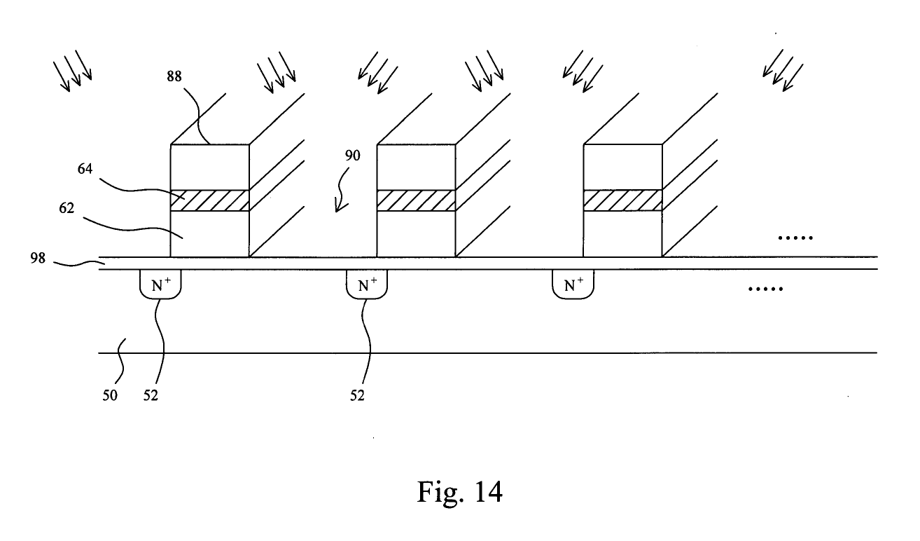

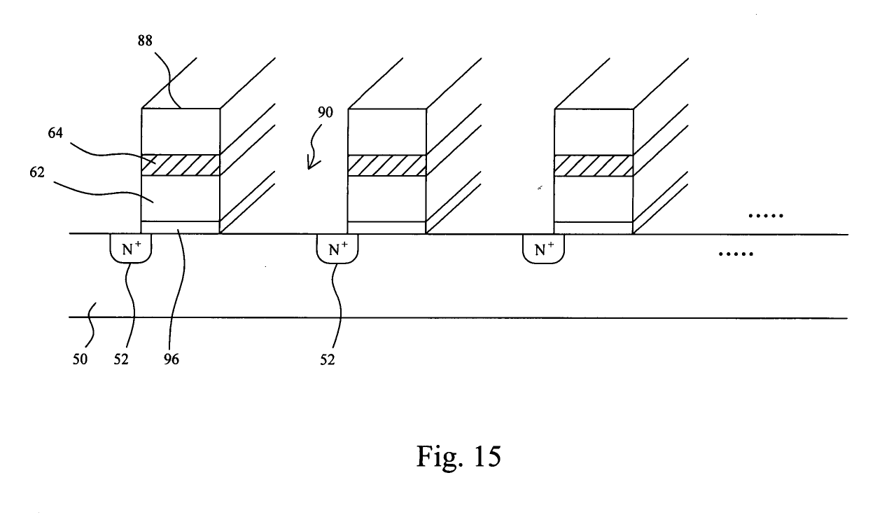

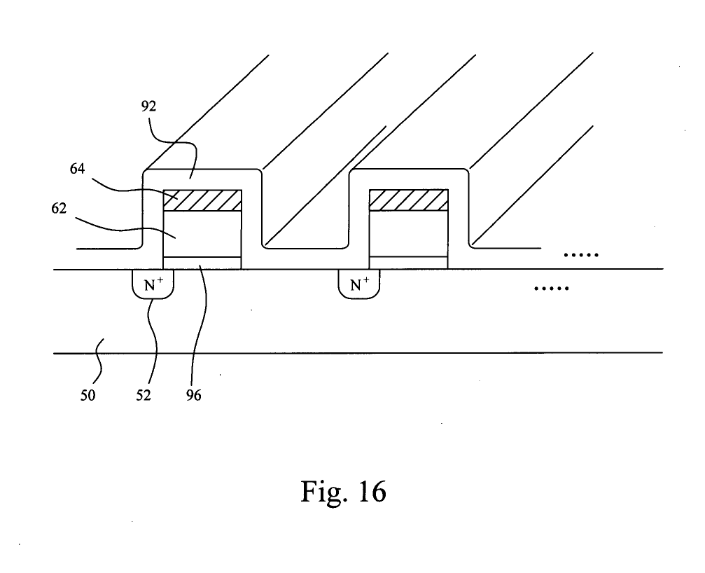

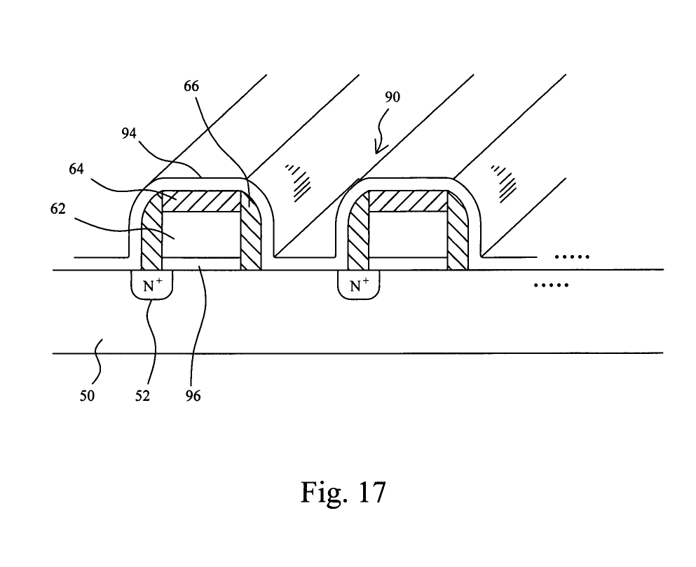

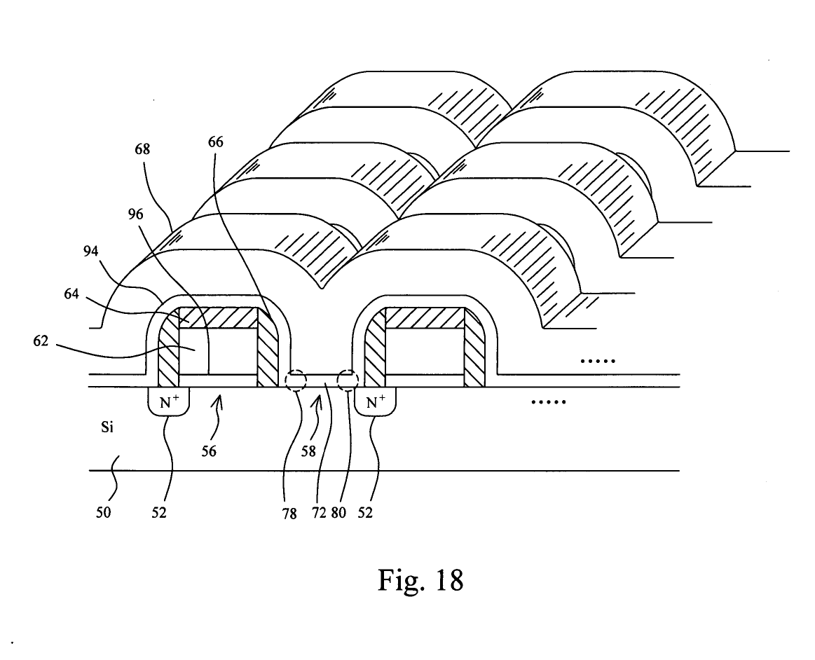

An embodiment process for forming the memory array of FIG. 11 is shown in FIGS. 13-18. Referring to FIG. 13, an oxide 98 and a gate conductor 84 of for example polysilicon are deposited on the substrate 50 and a cap 86 of silicon nitride or oxide is further deposited on the gate conductor 84. Then, the cap 86 and gate conductor 84 are patterned and etched to define the first gates with a photoresist 88, resulting in the first control gates 62 and their caps 64, as shown in FIG. 14. After tilt implantation of Arsenic or extra masking steps to form the bit lines 52 each on one side of the first control gates 62, the oxide 98 is etched to leave a portion thereof as the gate oxides 96 underlying the first control gates 62 and to expose the substrate 50 at the spaces 90 between the first control gates 62, as shown in FIG. 15. Then the photoresist 88 is striped off and a CVD oxide 92 is deposited, as shown in FIG. 16. Spacers 66 are formed on each sidewalls of the first gates by etching the CVD oxide 92, as shown in FIG. 17, and an ONO dielectric 94 is further deposited over the entire surface. As shown in FIG. 18, the second poly-gates 68 are formed by depositing a polysilicon, forming Tungsten silicide thereon and patterning the polysilicon and silicide.

To those skilled in the art, it is obvious that the first embodiment shown in FIG. 3 can be alternatively amended to arrange the gate dielectric on the right side of the spacer 66 is an oxide only and the left one is an ONO dielectric, instead of that shown in FIG. 11.

By the illustration of the above embodiments and descriptions, the inventive nonvolatile memory array has an increased memory density by introducing the common spacer dual gate cell structure between two neighbor bit lines. For higher memory density, to those skilled in the art, it is obvious that multi-level programming system can be employed for each charge storage location of the ONO gate dielectric to store more than two bits thereof.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

1. A common spacer dual gate memory cell comprising:
two bit lines on a semiconductor substrate;
a first channel for a first transistor and a second channel for a second transistor arranged in series between said two bit lines;
a first gate dielectric and a second gate dielectric above said first and second channels, respectively;
a first control gate and a second control gate above said first and second gate dielectrics, respectively; and
a spacer between said first and second control gates;
wherein at least one of said first and second gate dielectrics includes a silicon nitride.

2. A memory cell according to claim 1, further comprising a punch through region between said two bit lines.

3. A memory cell according to claim 1, wherein said first control gate extends along a first direction and said second control gate extends along a second direction perpendicular to said first direction.

4. A memory cell according to claim 1, wherein said second control gate has a portion crossing over above and isolated from said first control gate.

5. A memory cell according to claim 1, wherein said spacer is formed on a sidewall of said first control gate.

6. A memory cell according to claim 1, wherein said spacer and first control gate extend along a same direction.

7. A memory cell according to claim 1, wherein said second control gate has a portion crossing over above said spacer.

8. A memory cell according to claim 1, wherein said second control gate has a portion in a trench to contact said second gate dielectric.

9. A memory cell according to claim 1, wherein said first and second gate dielectrics each comprises a silicon nitride.

10. A memory cell according to claim 9, wherein one of said two transistors is completely turned on during the other one is read.

11. A memory cell according to claim 9, wherein one of said two transistors is completely turned on during the other one is programmed.

12. A memory cell according to claim 1, wherein one of said first and second gate dielectrics includes an oxide only.

13. A memory cell according to claim 12, wherein said oxide gated transistor is turned on during the other one is programmed.

14. A memory cell according to claim 12, wherein said oxide gated transistor is turned on during the other one is read.

15. A memory cell according to claim 1, wherein silicon nitride gated transistor is programmed with two charge storage locations.

16. A memory cell according to claim 15, wherein said two charge storage locations are programmed with a threshold voltage substantially different from each other.

17. A memory cell according to claim 1, wherein silicon nitride gated transistor is programmed with one charge storage location next to said spacer.

18-23. (canceled)
